(19) United States
(12) Patent Application Publication
(10) Pub. No.: US 2024/0395746 A1
(43) Pub. Date: Nov. 28, 2024

(54) SEMICONDUCTOR DIE HAVING A METAL PLATE LAYER

(71) Applicant: SK hynix Inc., Icheon-si Gyeonggi-do (KR)

(72) Inventors: Jae Jun LEE, Icheon-si Gyeonggi-do (KR); Sung Kyu KIM, Icheon-si Gyeonggi-do (KR); Jong Yeon KIM, Icheon-si Gyeonggi-do (KR); Ki Ill MOON, Icheon-si Gyeonggi-do (KR); Mi Seon LEE, Icheon-si Gyeonggi-do (KR)

(73) Assignee: SK hynix Inc., Icheon-si Gyeonggi-do (KR)

(21) Appl. No.: 18/497,654

(22) Filed: Oct. 30, 2023

(30) Foreign Application Priority Data
May 23, 2023 (KR) 10-2023-0066122

(51) Int. Cl. H01L 23/00; H01L 23/48; H01L 23/552

(52) U.S. Cl. CPC H01L 24/05; H01L 23/481; H01L 23/552; H01L 24/04; H01L 24/06; H01L 24/13; H01L 24/14; H01L 2224/0401; H01L 2224/05009; H01L 2224/05025; H01L 2224/05082; H01L 2224/05124; H01L 2224/05147; H01L 2224/05184; H01L 2224/0557; H01L 2224/05582; H01L 2224/05647; H01L 2224/05655; H01L 2224/05666; H01L 2224/05684; H01L 2224/06131; H01L 2224/06181; H01L 2224/06517; H01L 2224/13014; H01L 2224/13023; H01L 2224/13082; H01L 2224/13111; H01L 2224/13139; H01L 2224/13144; H01L 2224/13147; H01L 2224/13155; H01L 2224/14131; H01L 2224/14181; H01L 2224/14505; H01L 2224/14517; H01L 2924/0132

(57) ABSTRACT

In an embodiment, a semiconductor die includes a substrate, an interlayer insulating layer under a front-side surface the substrate, a horizontal metal interconnection in the interlayer insulating layer, a front-side pad under a lower surface of the interlayer insulating layer, a front-side bump structure under a lower surface of the front-side pad, a through-electrode vertically passing through the substrate, a back-side insulating layer over the back-side surface of the substrate, a first back-side metal plate layer over the back-side insulating layer, a back-side passivation layer over the back-side insulating layer and covering the first back-side metal plate layer, and a back-side bump structure over the through-electrode and the back-side passivation layer.

### CROSS-REFERENCE TO RELATED APPLICATIONS

The present application claims priority under 35 U.S.C. § 119 (a) to Korean Patent Application No. 10-2023-0066122, filed on May 23, 2023, in the Korean Intellectual Property Office, which is incorporated herein by reference in its entirety.

### BACKGROUND

### 1. Technical Field

Embodiments of the present disclosure generally provide for a semiconductor die, and more particularly, a semiconductor die having a metal plate layer.

### 2. Related Art

A warpage of a semiconductor die occurs during a semiconductor die manufacturing process.

### SUMMARY

An embodiment of the present disclosure provides a semiconductor die including a substrate having a front-side surface and a back-side surface; an interlayer insulating layer disposed under the front-side surface of the substrate; a horizontal metal interconnection disposed in the interlayer insulating layer; a front-side pad disposed under a lower surface of the interlayer insulating layer; a front-side bump structure disposed under a lower surface of the front-side pad; a through-electrode vertically passing through the substrate; a back-side insulating layer disposed over the back-side surface of the substrate; a first back-side metal plate layer disposed over the back-side insulating layer; a back-side passivation layer disposed over the back-side insulating layer and covering the first back-side metal plate layer; and a back-side bump structure disposed over the through-electrode and the back-side passivation layer. The through-electrode has a protruding portion that vertically passes through the back-side passivation layer and the first back-side metal plate layer. The protruding portion protrudes upward from the back-side surface of the substrate.

An embodiment of the present disclosure provides a semiconductor device including a substrate having a through-electrode area and a dummy area; an interlayer insulating layer disposed under an active surface of the substrate; a horizontal metal interconnection disposed in the interlayer insulating layer; a front-side passivation layer disposed under a lower surface of the interlayer insulating layer; a front-side bump structure disposed under a lower surface of the front-side passivation layer in the through-electrode area; a dummy front-side bump structure disposed under the lower surface of the front-side passivation layer in the dummy area; a back-side insulating layer disposed over an in-active surface of the substrate; a first back-side metal plate layer disposed over the back-side insulating layer; a back-side passivation layer disposed over the first back-side metal plate layer; a through-electrode vertically passing through the substrate, the back-side insulating layer, the first back-side metal plate layer, and the back-side passivation layer in the through-electrode area; a back-side bump structure disposed over the through-electrode in the through-electrode area; and a dummy back-side bump structure disposed over the back-side passivation layer in the dummy area.

### BRIEF DESCRIPTION OF THE DRAWINGS

FIG. 1 is a top view illustrating a back-side surface of a semiconductor die according to an embodiment of the present disclosure.

FIGS. 2A, 2B, 2C, 2D, and 2E are longitudinal cross-sectional views illustrating semiconductor dies according to embodiments of the present disclosure.

FIGS. 3A, 3B, 4A, 4B, 5A, and 5B are top views of semiconductor dies according to embodiments of the present disclosure and longitudinal cross-sectional views taken along the line I-I′ of FIG. 1.

### DETAILED DESCRIPTION

Embodiments will be described below in more detail with reference to the accompanying drawings. The embodiments may, however, be embodied in different forms and should not be construed as limited to the embodiments set forth herein. Throughout the disclosure, like reference numerals refer to like parts throughout the various figures and embodiments of the present invention.

It will be understood that, although the terms “first” and/or “second” may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

Other expressions that explain the relationship between elements, such as “between”, “directly between”, “adjacent to” or “directly adjacent to” should be construed in the same way.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. For example, it will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

An embodiment of the present disclosure provides a structure for preventing or reducing a warpage of a semiconductor die.

An embodiment of the present disclosure provides a semiconductor die having a metal plate layer.

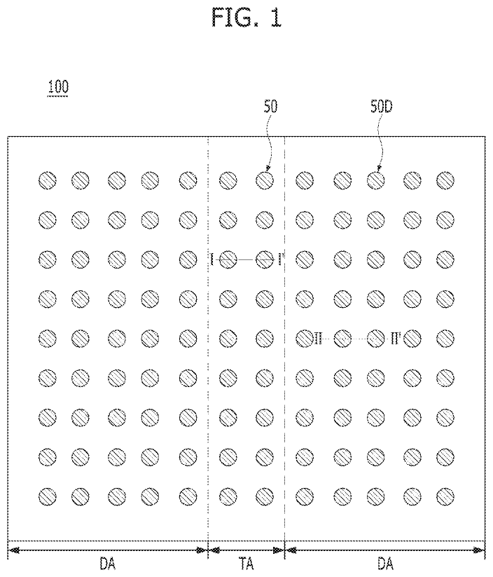

FIG. 1 is a top view illustrating a back-side surface of a semiconductor die 100 according to an embodiment of the present disclosure. Referring to FIG. 1, a semiconductor die 100 according to an embodiment of the present disclosure may include a through-electrode area TA and dummy areas DA. The through-electrode area TA may be disposed between the dummy areas DA. Back-side bump structures 50 may be disposed in the through-electrode area TA, and dummy back-side bump structures 50D may be disposed in the dummy area DA. The back-side bump structures 50 and the dummy back-side bump structures 50D may be arranged in a grid array shape.

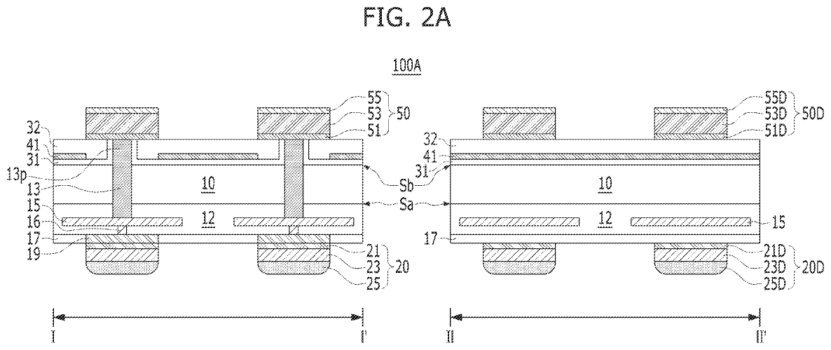

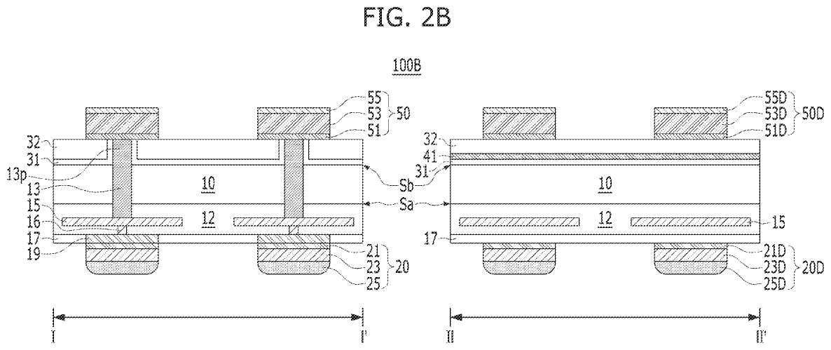

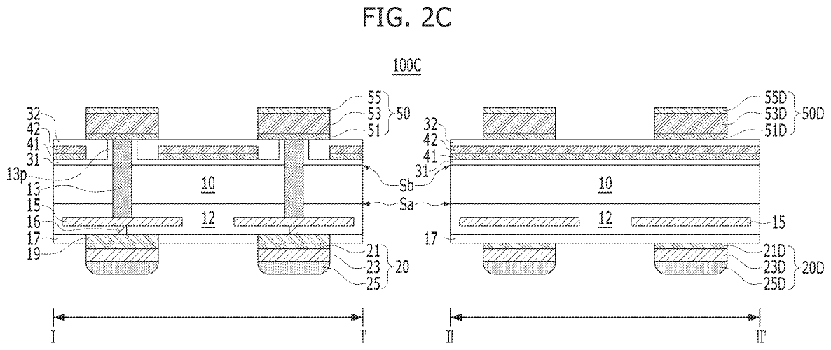

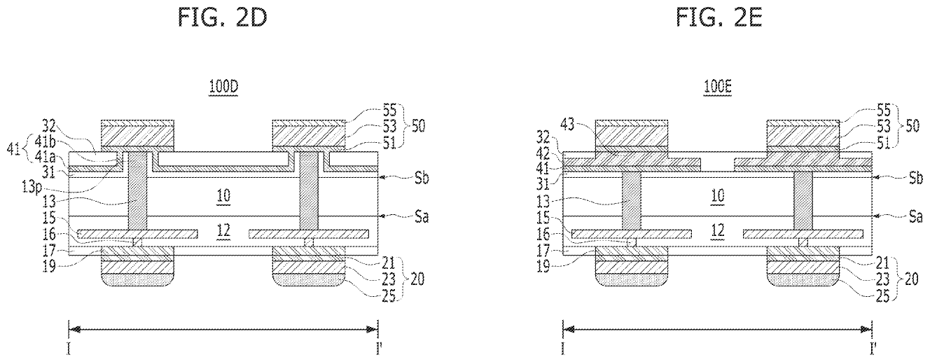

FIGS. 2A to 2E are longitudinal cross-sectional views illustrating semiconductor dies 100A-100E according to embodiments of the present disclosure. For example, FIGS. 2A to 2E are longitudinal cross-sectional views taken along the lines I-I′ and/or II-II′ of FIG. 1. Referring to FIGS. 1 and 2A, a semiconductor die 100A according to an embodiment of the present disclosure may include a substrate 10, through-electrodes 13, front-side bump structures 20, dummy front-side bump structures 20D, a first back-side metal plate layer 41, back-side bump structures 50, and dummy back-side bump structures 50D. The semiconductor die 100A may further include an interlayer insulating layer 12, horizontal metal interconnections 15, vertical via plugs 16, a front-side passivation layer 17, front-side pads 19, a back-side insulating layer 31, and a back-side passivation layer 32. The through-electrodes 13, the front-side bump structures 20, the back-side bump structures 50, the vertical via plugs 16, and the front-side pads 19 may be disposed in the through-electrode area TA. The dummy front-side bump structures 20D and the dummy back-side bump structures 50D may be disposed in the dummy areas DA. The interlayer insulating layer 12, the horizontal metal interconnections 15, the front-side passivation layer 17, the back-side passivation layer 32, and the first back-side metal plate layer 41 may be disposed in both the through-electrode area TA and the dummy area DA. In the through-electrode area TA, the through-electrodes 13, the horizontal metal interconnections 15, the vertical via plugs 16, the front-side pads 19, the front-side bump structures 20, and the back-side bump structures 50 may be electrically connected to each other. In the dummy areas DA, the horizontal metal interconnections 15, the dummy front-side bump structures 20D, and the dummy back-side bump structures 50D might not be electrically connected to each other.

The substrate 10 may include a semiconductor layer such as a silicon wafer, a silicon germanium wafer, an epitaxially grown silicon layer, an epitaxially grown silicon germanium layer, or SOI (silicon on insulator). In an embodiment, the substrate 10 may include a silicon wafer. The substrate 10 may have a front-side surface Sa and a back-side surface Sb. The front-side surface Sa may correspond to an active surface of the substrate 10, and the back-side surface Sb may correspond to an in-active surface of the substrate 10. For example, active circuit elements such as transistors may be disposed on the front-side surface Sa of the substrate 10, and any active circuit elements might not be disposed on the back-side surface Sb of the substrate 10. In the drawing, the front-side surface Sa of the substrate 10 may face downward, and the back-side surface Sb of the substrate 10 may face upward.

Electrical circuit elements such as transistors and metal interconnections may be disposed on the front-side surface Sa of the substrate 10. The interlayer insulating layer 12 may be disposed on the front-side surface Sa of the substrate 10 to cover the electrical circuit elements. The interlayer insulating layer 12 may include a silicon oxide-based insulating layer and a silicon nitride-based insulating layer.

The through-electrodes 13 may vertically pass through the substrate 10. The through-electrodes 13 may pass through a portion of the interlayer insulating layer 12. The through-electrodes 13 may include protruding portions 13p protruding upward from the back-side surface Sb of the substrate 10 to be exposed. For example, top ends of the through-electrodes 13 may protrude upward from the back-side surface of the substrate 10 to be exposed. The through-electrodes 13 may include copper.

The horizontal metal interconnections 15 may be connected to end portions of the through-electrodes 13 in the interlayer insulating layer 12. Although not shown, the horizontal metal interconnections 15 may include a plurality of metal layers extending in a horizontal direction. The horizontal metal interconnections 15 may include a metal such as copper or tungsten.

The vertical via plugs 16 may vertically pass through the interlayer insulating layer 12 and electrically connect the horizontal metal interconnections 15 to the front-side pads 19 in a vertical direction, respectively. In an embodiment, the vertical via plugs 16 may include a metal such as copper or tungsten.

The front-side passivation layer 17 may be disposed under a lower surface of the interlayer insulating layer 12 disposed under the front-side surface Sa of the substrate 10. The front-side passivation layer 17 may include an insulating material such as silicon oxide or silicon nitride. The front-side passivation layer 17 may surround side surfaces of the front-side pads 19. The front-side passivation layer 17 may expose lower surfaces of the front-side pads 19.

In an embodiment, the front-side pads 19 may include metal. For example, the front-side pads 19 may include aluminum or tungsten. The front-side pads 19 may correspond to the top metal layer among multiple metal layers of the electrical circuit elements of semiconductor devices.

The front-side bump structures 20 may be disposed under the lower surfaces of the front-side pads 19 in the through-electrode area TA. In the dummy areas DA, the dummy front-side bump structures 20D may be disposed under a lower surface of the front-side passivation layer 17. The front-side bump structures 20 may be electrically connected to the through-electrodes 13, and the dummy front-side bump structures 20D might not be electrically connected to the through-electrodes 13.

Each of the front-side bump structures 20 may include a front-side UBM (Under Bump Metallurgy) layer 21, a front-side bump body 23, and a solder layer 25. Each of the dummy front-side bump structures 20D may include a dummy front-side UBM layer 21D, a dummy front-side bump body 23D, and a dummy solder layer 25D.

The front-side UBM layers 21 may be disposed directly under the lower surfaces of the front-side pads 19. The dummy front-side UBM layers 21D may be disposed directly under the lower surface of the front-side passivation layer 17. Each of the front-side UBM layers 21 and each of the dummy front-side UBM layers 21D may include a lower UBM layer and an upper UBM layer. The lower UBM layer may include a metal to reinforce an adhesive force to the front-side passivation layer 17 and the front-side pads 19. For example, the lower UBM layer may include a titanium layer or a titanium tungsten layer. The upper UBM layer may include at least one of a copper layer and a nickel layer. The upper UBM layer may be used as a seed layer in a plating process for forming the front-side bump body 23 and the dummy front-side bump body 23D. The front-side bump body 23 and the dummy front-side bump body 23D may include a metal having conductivity. For example, the bump body 23 and the dummy front-side bump body 23D may include at least one of nickel or copper. In an embodiment, the front-side bump body 23 and the dummy front-side bump body 23D may include nickel having corrosion resistance. The solder layers 25 and the dummy solder layers 25D may include an alloy of metals such as tin (Sn) and silver (Ag).

The back-side insulating layer 31 may be conformally disposed on the back-side surface Sb of the substrate 10. Portions of the back-side insulating layer 31 may protrude upward to surround side surfaces of the protruding portions 13p of the through-electrodes 13 protruding upward from the back-side Sb of the substrate 10 to be exposed. For example, the back-side insulating layer 31 may be conformally disposed on the back-side surface Sb of the substrate 10 and on the side surfaces of the protruding portions 13p of the through-electrodes 13. The protruding portions of the back-side insulating layer 31 may have a cylinder shape or a tube shape. The back-side insulating layer 31 may include a silicon nitride-based insulating material.

The first back-side metal plate layer 41 may be disposed on the back-side insulating layer 31 in a plate shape. The first back-side metal plate layer 41 may be disposed to be horizontally spaced apart from the through-electrodes 13 in the through-electrode area TA. The first back-side metal plate layer 41 may include double layers having a lower metal layer and an upper metal layer. The lower metal layer may, in an embodiment, include a metallic adhesive layer to increase bonding strength between the upper metal layer and the back-side insulating layer 31. For example, the lower metal layer may include a titanium layer or a titanium tungsten layer. The upper metal layer may include at least one of metals such as copper or nickel. The first back-side metal plate layer 41 may be formed using a physical vapor deposition (PVD) process such as sputtering. For example, both the lower metal layer and the upper metal layer may be formed using the PVD process.

The back-side passivation layer 32 may be disposed on the back-side insulating layer 31 to cover the first back-side metal plate layer 41. The back-side passivation layer 32 may surround the protruding portions of the back-side insulating layer 31 surrounding the sides of the protruding portions 13p of the through-electrodes 13. Top end surfaces of the through-electrodes 13, top end surfaces of the back-side insulating layer 31, and top surface of the back-side passivation layer 32 may be coplanar.

Each of the back-side bump structures 50 may include a back-side UBM layer 51, a back-side bump body 53, and a back-side bump capping layer 55. Each of the dummy back-side bump structure 50D may include a dummy back-side UBM layer 51D, a dummy back-side bump body 53D, and a dummy back-side bump capping layer 55D. In the through-electrode area TA, the back-side UBM layer 51 may be disposed on the top surface of the back-side passivation layer 32, the top end surface of the back-side insulation layer 31, and the top ends of the penetrating electrodes 13. In the dummy areas DA, the dummy back-side UBM layer 51D may be disposed on the top surface of the back-side passivation layer 32. The back-side UBM layer 51 and the dummy back-side UBM layer 51D may include a lower UBM layer and an upper UBM layer, respectively. The lower UBM layer may include a metal layer such as a titanium layer or a titanium tungsten layer. The upper UBM layer may include the same metal as the bump body 53. The upper UBM layer may include at least one of copper or nickel. The upper UBM layer may be used as a seed layer in a plating process for forming the back-side bump body 53 and the dummy back-side bump body 53D. The back-side bump body 53 and the dummy back-side bump body 53D may include at least one of nickel or copper. The back-side bump capping layer 55 and the dummy back-side bump capping layer 55D may include a metal diffusion barrier layer such as nickel or an oxidation-resistive metal or a corrosion-resistive metal such as gold. The back-side bump structures 50 may be vertically aligned with and electrically connected to the through-electrodes 13, respectively. The dummy back-side bump structures 50D might not be vertically aligned with and might not be electrically connected to the through-electrodes 13.

The first back-side metal plate layer 41 may compensate for thermal expansion of metal layers and insulating material layers disposed on the front-side surface Sa of the substrate 10. Accordingly, the first back-side metal plate layer 41 can prevent, alleviate, and compensate warpage and bending of the substrate 10, the interlayer insulating layer 12, the horizontal metal wires 15, the front-side passivation layer 17, the back-side insulating layer 31, and the back-side passivation layer 32. In addition, the first back-side metal plate layer 41 may prevent and alleviate delamination between elements.

Referring to FIG. 2B, a semiconductor die 100B according to an embodiment of the present disclosure may include a substrate 10, through-electrodes 13, front-side bump structures 20, dummy front-side bump structures 20D, first back-side metal plate layer 41, back-side bump structures 50, and dummy back-side bump structures 50D. The first back-side metal plate layer 41 may be disposed only in the dummy area DA. The first back-side metal plate layer 41 might not be disposed in the through-electrode area TA. The first back-side metal plate layer 41 may be selectively disposed at selected positions. For example, when operation of the semiconductor die 100B is affected by a parasitic capacitance or an electrical interference between the first back-side metal plate layer 41 and the through-electrodes 13, the first back-side metal plate layer 41 may be omitted in the through-electrode area TA.

Referring to FIG. 2C, a semiconductor die 100C according to an embodiment of the present disclosure may further include a second back-side metal plate layer 42 disposed on the first back-side metal plate layer 41. In an embodiment, the second back-side metal plate layer 42 may include the same metal as the upper metal layer of the first back-side metal plate layer 41. For example, the second back-side metal plate layer 42 may include at least one of copper or nickel. The first back-side metal plate layer 41 may include a lower metal layer and an upper metal layer formed by PVD processes. The second back-side metal plate layer 42 may include a metal layer formed by a plating process.

In another embodiment, the first back-side metal plate layer 41 may be a single layer including a titanium layer or a titanium tungsten layer formed by performing the PVD process. The second back-side metal plate layer 42 may be a double layer including a lower metal layer formed by performing the PVD process and an upper metal layer formed by performing the plating process. In the embodiment, the lower metal layer and the upper metal layer of the second back-side metal plate layer 42 may include at least one of copper or nickel. For example, the lower metal layer and the upper metal layer of the second back-side metal plate layer 42 may include the same metal. The second back-side metal plate layer 42 may be twice or more thicker than the first back-side metal plate layer 41. Side surfaces of the first back-side metal plate layer 41 and side surfaces of the second back-side metal plate layer 42 may be substantially vertically aligned with each other. In an embodiment, the side surfaces of the first back-side metal plate layer 41 may be under-cut below the lower surface of the second back-side metal plate layer 42. The second back-side metal plate layer 42 may be disposed in both the through-electrode area TA and the dummy area DA. In another embodiment, the second back-side metal plate layer 42 might not be disposed in the through-electrode area TA. The second back-side metal plate layer 42 may be disposed only in the dummy areas DA.

In a viewpoint of a process for forming the first back-side metal plate layer 41, in an embodiment, when a PVD process and an etching process are difficult to be performed, the second back-side metal plate layer 42 having a sufficient thickness may be formed using the plating process. For example, the second back-side metal plate layer 42 may be formed to be twice or thicker than the first back-side metal plate layer 41. In an embodiment, by adding the second back-side metal plate layer 42, warpage resistance and bending resistance may be further enhanced. For example, when the first back-side metal plate layer 41 does not sufficiently prevent the warpage and bending of the substrate 10, the second back-side metal plate layer 42 which is thicker than the first back-side metal plate layer 41 can reinforce the warpage resistance and the bending resistance.

Referring to FIG. 2D, a semiconductor die 100D according to an embodiment of the present disclosure may include a first back-side metal plate layer 41 electrically connected to the back-side bump structure 50. A portion of the first back-side insulating layer 31 may protrude to conformally surround a side surface of the protruding portion 13p of the through-electrode 13. The first back-side metal plate layer 41 may include a horizontal plate portion 41a and a vertical protruding portion 41b. The horizontal plate portion 41a may have a plate shape between the back-side insulating layer 31 and the back-side passivation layer 32. The vertical protruding portion 41b may surround the side surface of the protruding portion of the back-side insulating layer 31 surrounding the side surfaces of the protruding portion 13p of the through-electrode 13. The vertical protruding portion 41b may protrude upward from the horizontal plate portion 41a to have a cylindrical shape or a tube shape. Accordingly, the first back-side metal plate layer 41 and the back-side UBM layers 51 of the back-side bump structure 50 may be physically and electrically connected to each other. When the through-electrode 13 and the back-side bump structure 50 transmit a common electrical signal, such as a common power voltage or a ground voltage, the first back-side metal plate layer 41 may electrically connect the through-electrode 13 to the back-side bump structure 50 such as a power plane or a ground plane. Accordingly, the first back-side metal plate layer 41 may provide a stable power supply effect, a decoupling effect, a shielding effect, and other electrical stabilization effects.

Referring to FIG. 2E, a semiconductor die 100E according to an embodiment of the present disclosure may include a substrate 10, through-electrode 13, front-side bump structure 20, first and second back-side metal plate layers 41 and 42, and back-side bump structure 50. The first and second back-side metal plate layers 41 and 42 may be disposed on the through-electrode 13. The semiconductor die 100E may further include metal pattern 43 disposed on the second back-side metal plate layer 42. The metal pattern 43 may be disposed between the second back-side metal plate layer 42 and the back-side bump structure 50. The metal pattern 43 may be disposed on a portion of a top surface of the second back-side metal plate layer 42 in an upwardly protruding shape. The second back-side metal plate layer 42 and the metal pattern 43 may form a staircase. The metal pattern 43 may be vertically aligned with the through-electrode 13 and/or the back-side bump structure 50. The metal pattern 43 may include the same metal as the second back-side metal plate layer 42. Accordingly, in an embodiment, an interface between the second back-side metal plate layer 42 and the metal pattern 43 may exist virtually or may exist. The first back-side metal plate layer 41, the second back-side metal plate layer 42, the metal pattern 43, and the back-side bump structure 50 may be electrically connected with other.

In another embodiment, the back-side UBM layer 51 may be omitted. For example, the metal pattern 43 and the back-side bump body 53 may include the same material to be materially continued with each other.

In another embodiment, the second back-side metal plate layer 42 may be omitted. For example, the metal pattern 43 may be directly disposed on the first back-side metal plate layer 41 in a mesa shape upwardly protruding. Accordingly, the metal pattern 43 may be disposed between the first back-side metal plate layer 41 and the back-side bump structure 50.

The semiconductor dies 100A-100E according to the embodiments of the present disclosure may include the back-side metal plate layers 41 and 42 and the metal pattern 43 disposed on the back-side surface Sb of the substrate 10. Accordingly, in an embodiment, warpages caused by differences in thermal expansion rates among the multiple metal layers and the insulating layers disposed under the front-side surface Sa of the substrate 10 can be prevented, alleviated, and compensated.

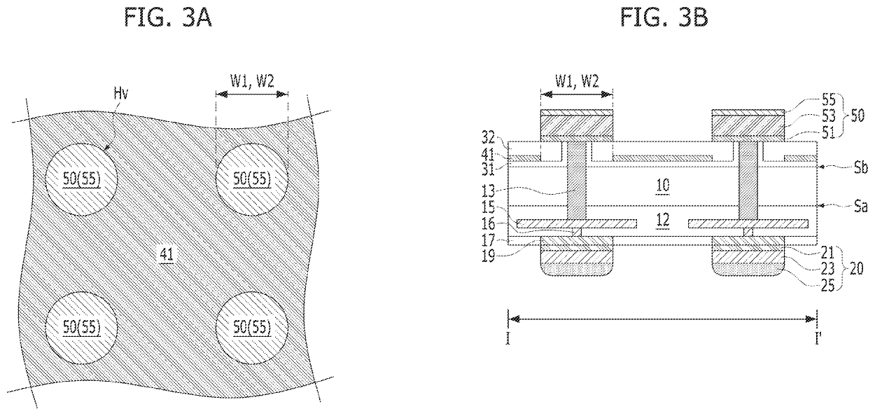

FIGS. 3A and 3B to 5A and 5B are top views of semiconductor dies according to embodiments of the present disclosure and longitudinal cross-sectional views taken along the line I-I′ of FIG. 1. Referring to FIGS. 3A and 3B, the first back-side metal plate layer 41 may include through-electrode holes Hv each having a circular shape. The first back-side metal plate layer 41 and the back-side bump structures 50 might not be vertically overlapped with each other. In an embodiment, the maximum width (or diameter) W1 of the through-electrode holes Hv of the first back-side metal plate layer 41 and the maximum width (or diameter) W2 of the back-side bump structures 50 may be substantially the same.

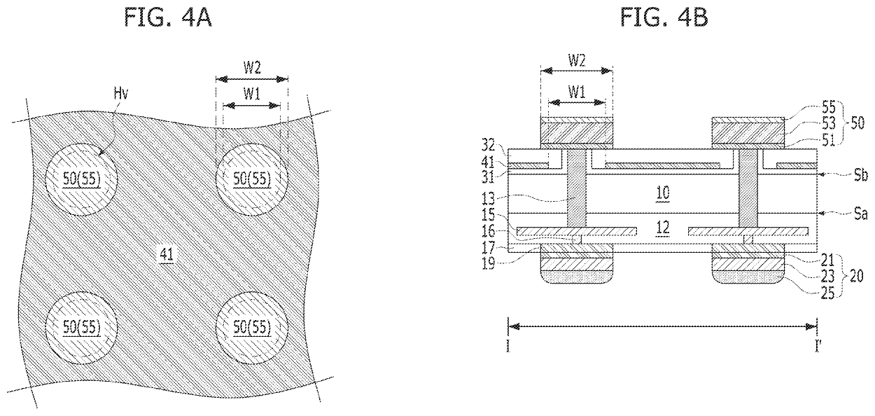

Referring to FIGS. 4A and 4B, the first back-side metal plate layer 41 and the back-side bump structures 50 may be partially vertically overlapped with each other. For example, in a vertical direction, portions of the first back-side metal plate layer 41 may be located between the back-side insulating layer 31 and the back-side bump structures 50. For example, the maximum width (or diameter) W1 of the through-electrode holes Hv of the first back-side metal plate layer 41 may be less than the maximum width (or diameter) W2 of the back-side bump structures 50. In FIG. 4A, the side surfaces of the first back-side metal plate layer 41 are indicated by dotted lines. When a decoupling effect or a shielding effect occurs between the through-electrodes 13 and the back-side bump structures 50, and the first back-side metal plate layer 41, the present embodiment can be applied.

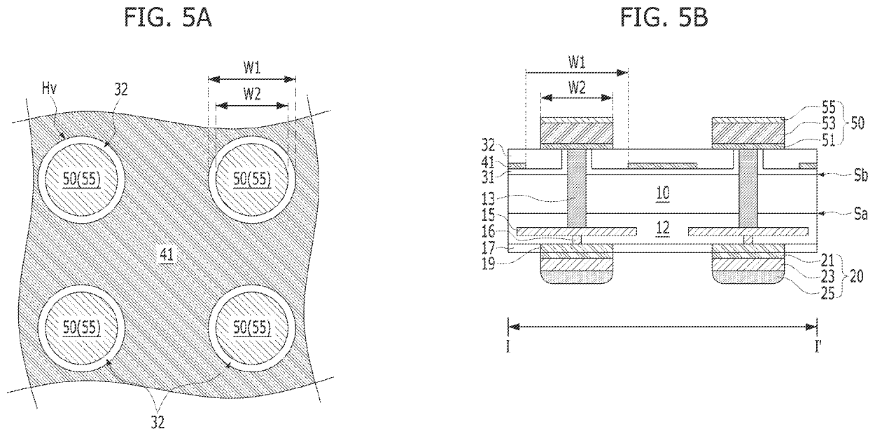

Referring to FIGS. 5A and 5B, in an embodiment, the first back-side metal plate layer 41 and the back-side bump structures 50 might not be overlapped with each other in the vertical direction. For example, the maximum width (or diameter) W1 of the through-electrode holes Hv of the first back-side metal plate layer 41 may be greater than the maximum width (or diameter) W2 of the back-side bump structures 50. In a top view, the back-side passivation layer 32 may be exposed between the sides of the first back-side metal plate layer 41 and the sides of the back-side bump structures 50. When signal interferences occur between the through-electrodes 13 and the back-side bump structures 50 and the first back-side metal plate layer

In FIGS. 3A and 3B to 5A and 5B, in an embodiment, the first back-side metal plate layer 41 can be replaced with the second back-side metal plate layer 42. That is, the first back-side metal plate layer 41 may include the second back-side metal plate layer 42. Accordingly, in an embodiment, a process for manufacturing a semiconductor device can be simplified.

According to various embodiments of the present disclosure, a warpage occurring in the semiconductor die manufacturing process may be prevented and reduced.

While various embodiments have been described with respect to the specific embodiments, it will be apparent to those skilled in the art, in light of this disclosure, that various changes and modifications may be made without departing from the spirit and scope of the embodiments as defined in the following claims.

What is claimed is:

1. A semiconductor die comprising:
a substrate having a front-side surface and a back-side surface;
an interlayer insulating layer disposed under the front-side surface of the substrate;
a horizontal metal interconnection disposed in the interlayer insulating layer;
a front-side pad disposed under a lower surface of the interlayer insulating layer;
a front-side bump structure disposed under a lower surface of the front-side pad;
a through-electrode vertically passing through the substrate;
a back-side insulating layer disposed over the back-side surface of the substrate;
a first back-side metal plate layer disposed over the back-side insulating layer;
a back-side passivation layer disposed over the back-side insulating layer and covering the first back-side metal plate layer; and
a back-side bump structure disposed over the through-electrode and the back-side passivation layer,
wherein the through-electrode has a protruding portion that vertically passes through the back-side passivation layer and the first back-side metal plate layer, wherein the protruding portion protrudes upward from the back-side surface of the substrate.

2. The semiconductor die of claim 1, further comprising:
a front-side passivation layer disposed under the lower surface of the interlayer insulating layer to expose the lower surface of the front-side pad and surround a side surface of the front-side pad.

3. The semiconductor die of claim 2, further comprising:
a dummy front-side bump structure disposed under the front-side passivation layer and a dummy back-side bump structure disposed over the back-side passivation layer,
wherein the substrate includes a through-electrode area in which the through-electrodes are disposed and a dummy area in which the through-electrodes are not disposed, and
wherein the dummy front-side bump structure and the dummy back-side bump structure are disposed in the dummy area.

4. The semiconductor die of claim 1,
wherein the front-side bump structure includes:
a front-side UBM (Under Bump Metallurgy) layer;
a front-side bump body disposed under a lower surface of the front-side UBM layer; and
a solder layer under the lower surface of the front-side bump body above, and
wherein the back-side bump structure includes:
a back-side UBM layer;
a back-side bump body disposed over the back-side UBM layer; and
a back-side bump capping layer disposed over the back-side bump body.

5. The semiconductor die of claim 1,
wherein the first back-side metal plate layer include multi layers,
wherein the multi layers include:
a lower metal layer including titanium: and
an upper metal layer including at least one of copper and nickel.

6. The semiconductor die of claim 1,
wherein the first back-side metal plate layer has a through-electrode hole, and
wherein the through-electrode passes vertically through the through-electrode hole.

7. The semiconductor die of claim 1,
wherein a portion of the back-side insulating layer protrudes to conformally surround the side surface of the protruding portion of the through-electrode.

8. The semiconductor die of claim 7,
wherein the portion of the back-side insulating layer has substantially a cylindrical shape or substantially a tube shape.

9. The semiconductor die of claim 1,
wherein the first back-side metal plate layer includes:
a horizontal plate portion disposed between the back-side insulating layer and the back-side passivation layer to have substantially a plate shape; and
a vertical protruding portion surrounding a side of the back-side insulating layer surrounding the protruding portion of the through-electrode.

10. The semiconductor die of claim 9,
wherein the vertical protruding portion of the first back-side metal plate layer is in contact with the back-side bump structure.

11. The semiconductor die of claim 9,
wherein the vertical protruding portion of the first back-side metal plate layer has substantially a cylindrical shape or substantially a tube shape.

12. The semiconductor die of claim 1, further comprising:
a metal pattern disposed between the first back-side metal plate layer and the back-side bump structure, and
wherein the metal pattern is vertically aligned with the through- electrode and the back-side bump structure.

13. The semiconductor die of claim 12,
wherein the metal pattern is disposed over the first back-side metal plate layer and has a protruding shape upward to be in contact with the through-electrode and the back-side bump structure.

14. A semiconductor device comprising:
a substrate having a through-electrode area and a dummy area;
an interlayer insulating layer disposed under an active surface of the substrate;
a horizontal metal interconnection disposed in the interlayer insulating layer;
a front-side passivation layer disposed under a lower surface of the interlayer insulating layer;
a front-side bump structure disposed under a lower surface of the front-side passivation layer in the through-electrode area;
a dummy front-side bump structure disposed under the lower surface of the front-side passivation layer in the dummy area;
a back-side insulating layer disposed over an in-active surface of the substrate;
a first back-side metal plate layer disposed over the back-side insulating layer;
a back-side passivation layer disposed over the first back-side metal plate layer;
a through-electrode vertically passing through the substrate, the back-side insulating layer, the first back-side metal plate layer, and the back-side passivation layer in the through-electrode area;
a back-side bump structure disposed over the through-electrode in the through-electrode area; and
a dummy back-side bump structure disposed over the back-side passivation layer in the dummy area.

15. The semiconductor die of claim 14,
wherein the through-electrode has a protruding portion protruding upward from the in-active surface of the substrate, and
wherein a portion of the back-side insulating layer protrudes to surround a side surface of the protruding portion of the through-electrode.

16. The semiconductor die of claim 14, wherein the first back-side metal plate layer has a through-electrode hole, and
wherein the through-electrode passes vertically through the through-electrode hole.

17. The semiconductor die of claim 14,
wherein the first back-side metal plate layer includes a lower UBM (Under Bump Metallurgy) layer including titanium and an upper UBM layer including at least one of copper and nickel.

18. The semiconductor die of claim 14,
wherein the first back-side metal plate layer is connected to the back-side bump structure.

19. The semiconductor die of claim 14, further comprising:
a metal pattern disposed between the first back-side metal plate layer and the back-side bump structure,
wherein the first back-side metal plate layer extends onto the protruding portion of the through-electrode, and
wherein the metal pattern is disposed over the first back-side metal plate layer to be vertically aligned with the through-electrode and the back-side bump structure.

20. The semiconductor die of claim 14,
wherein the first back-side metal plate layer is disposed in the dummy region.
